(19) United States
(12) Patent Application Publication
(10) Pub. No.: US 2026/0107506 A1
(43) Pub. Date: Apr. 16, 2026

(54) SEMICONDUCTOR DEVICE AND METHODS OF FORMING THE SAME

(71) Applicant: TAIWAN SEMICONDUCTOR MANUFACTURING COMPANY, LTD., Hsinchu (TW)

(72) Inventor: Tzu-Ging LIN, Kaohsiung (TW)

(21) Appl. No.: 18/911,416

(22) Filed: Oct. 10, 2024

(51) Int. Cl. H01L 29/417; H01L 21/285; H01L 29/06; H01L 29/423; H01L 29/66; H01L 29/775; H01L 29/786

(52) U.S. Cl. CPC H10D 30/6729; H10D 30/014; H10D 30/43; H10D 30/6735; H10D 30/6757; H10D 62/121; H10D 64/0112; H10D 64/017; H10D 64/254

(57) ABSTRACT

Embodiments of the present disclosure provide semiconductor devices and methods of forming the same. An exemplary semiconductor device of the present disclosure includes a first channel region disposed over a semiconductor substrate; a gate structure disposed over the first channel region; a first source/drain region disposed at a first side of the first channel region; a second source/drain region disposed at a second side of the first channel region; an interlayer dielectric layer disposed over the first channel region, the first source/drain region, and the second source/drain region; a first contact disposed in the interlayer dielectric layer and electrically coupled to the first source/drain region; and a second contact disposed in the semiconductor substrate and electrically coupled to the second source/drain region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-6 are perspective views of intermediate stages of manufacturing a semiconductor device, in accordance with some embodiments.

FIGS. 7A-23B and 25A-25B are cross-sectional side views of intermediate stages of manufacturing the semiconductor device, in accordance with some embodiments.

FIG. 24 illustrates the device on/off transition regimes of a semiconductor device of the present disclosure and an ordinary semiconductor device.

FIGS. 26A and 26B are cross-sectional views of intermediate stages of manufacturing the semiconductor device, in accordance with some embodiments.

FIGS. 27A and 27B are cross-sectional views of intermediate stages of manufacturing the semiconductor device, in accordance with some embodiments.

FIGS. 28A and 28B are cross-sectional views of intermediate stages of manufacturing the semiconductor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a transistor structure including a plurality of nanostructure channels disposed between source/drain regions, and the plurality of the nanostructure channels have a same length. In some embodiments, the transistor structure also includes a frontside contact electrically coupled to a frontside of one of the source/drain regions and a backside contact electrically coupled to a backside of the other source/drain region. As such, regardless of which nanostructure channel the current transmits through, the transmission distances between the contacts would be the same. The transistor structure of the present disclosure can, therefore, have a sharp on-off transition.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, FinFETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

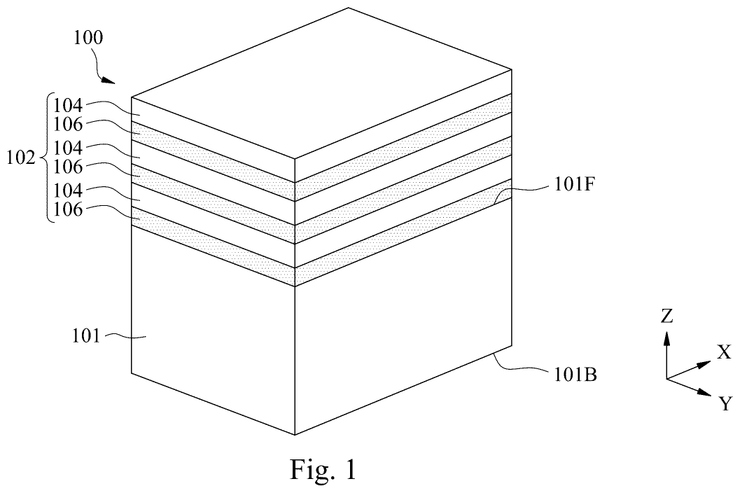

FIGS. 1-23B and 25A-25B show exemplary processes for manufacturing a semiconductor device 100 according to embodiments of the present disclosure. It is understood that additional operations can be provided before, during, and after processes shown by FIGS. 1-23B and 25A-25B, and some of the operations described below can be replaced or eliminated, for additional embodiments of the method. The order of the operations/processes is not limiting and may be interchangeable.

FIGS. 1-6 are perspective views of intermediate stages in manufacturing a semiconductor device 100, in accordance with some embodiments. As shown in FIG. 1, a semiconductor device 100 includes a substrate 101 having a frontside 101F and a backside 101B opposite to the frontside 101F. The semiconductor device 100 also includes a multilayer stack 102 formed over the frontside 101F of the substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity) in the frontside 101F of the substrate 101. Depending on circuit design, the substrate 101 may include p-type doped wells for an n-type field effect transistors (NFET) n-type doped wells for a p-type field effect transistors (PFET).

The multilayer stack 102 includes alternating semiconductor layers made of different materials to facilitate the formation of nanostructure channels in a multi-gate device, such as nanostructure channel FETs. In some embodiments, the multilayer stack 102 includes first semiconductor layers 104 and second semiconductor layers 106 that are alternately stacked over the frontside 101F of the substrate 101. For example, the multilayer stack 102 is illustrated as including three layers of first semiconductor layers 104 and three layers of second semiconductor layers 106 for illustrative purposes. It is appreciated that any number of the first and second semiconductor layers 104, 106 can be included in the multilayer stack 102. In some embodiments, the first semiconductor layers 104 are formed of a first semiconductor material, and the second semiconductor layers 106 are formed of a second semiconductor material different from the first semiconductor material. The second semiconductor material may have a different etch selectively and/or oxidation rate than the first semiconductor material. In some embodiments, either the first semiconductor material or the second semiconductor material is or includes a material such as SiGe, SiC, GeAs, GaP, InP, InAs, InSb, GaAsP, AlInAs, AlGaAs, InGaAs, GaInP, GaInAsP, combinations thereof, or the like. In some embodiments, the first semiconductor material is formed of Si, and the second semiconductor material is formed of SiGe, or vice versa.

Each first semiconductor layer 104 may have a thickness in a range between about 5 nm and about 30 nm. Each second semiconductor layer 106 may have a thickness that is equal, less, or greater than the thickness of the first semiconductor layer 104. In some embodiments, each second semiconductor layer 106 has a thickness in a range between about 2 nm and about 50 nm. The first and second semiconductor layers 104, 106 are formed by any suitable deposition process, such as epitaxy deposition. By way of example, the epitaxial deposition of the multilayer stack 102 may be performed by vapor-phase epitaxy (VPE), molecular beam epitaxy (MBE), chemical vapor deposition (CVD), low-pressure metalorganic chemical vapor deposition (MOCVD) process, atomic layer deposition (ALD), the like, and/or other suitable epitaxial growth processes.

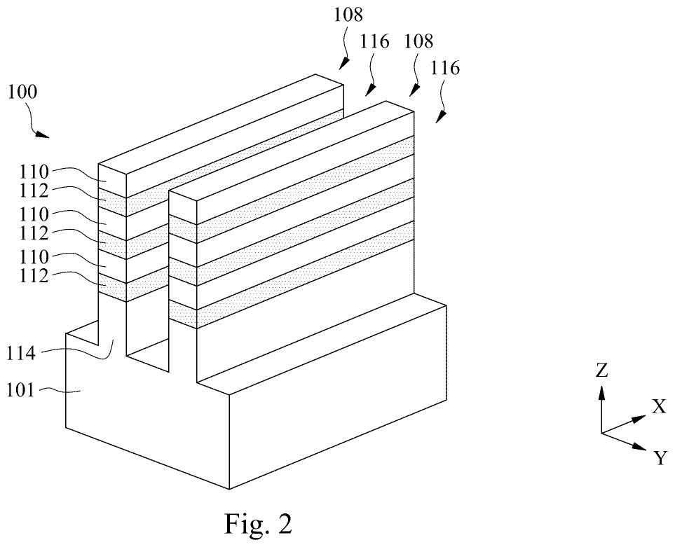

In FIG. 2, the multilayer stack 102 and the substrate 101 are patterned by one or more etch processes, in accordance with some embodiments. Each semiconductor strip 108 may include first nanostructures 110 patterned from the first semiconductor layers 104 and second nanostructures 112 patterned from the second semiconductor layers 106. The substrate 101 may include a plurality of fins 114 after the etch processes. The semiconductor strips 108 are disposed over the fins 114, respectively. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section.

The semiconductor strips 108 may be formed by patterning a hard mask layer (not shown) formed on the multilayer stack 102 using multi-patterning operations that include lithography and etch processes. The etch process can include dry etching such as reactive ion etching (RIE) or neutral beam etching (NBE), wet etching, and/or other suitable processes. The lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etch process forms trenches 116 in unprotected regions through the hard mask layer, through the multilayer stack 102, and into the substrate 101, thereby leaving the semiconductor strips 108 and the fins 114. The trenches 116 extend along the X direction. In some embodiments, the semiconductor strips 108 and the fins 114 have a longitudinal axis along the X direction.

The semiconductor device 100 may include a plurality of transistor structures. The first nanostructures 110 or portions thereof may form nanostructure channel(s) of the transistor structures in later fabrication stages, while the second nanostructures 112 may act as sacrificial layers in later fabrication stages for allowing the nanostructure channel(s) to be surrounded by gate structures. The transistor structures having the nanostructure channel(s) may be referred to as nanostructure transistors, nanosheet transistors, nanowire transistors, gate-all-around (GAA) transistors, multi-bridge channel (MBC) transistors, or any transistors having gate electrodes surrounding channels.

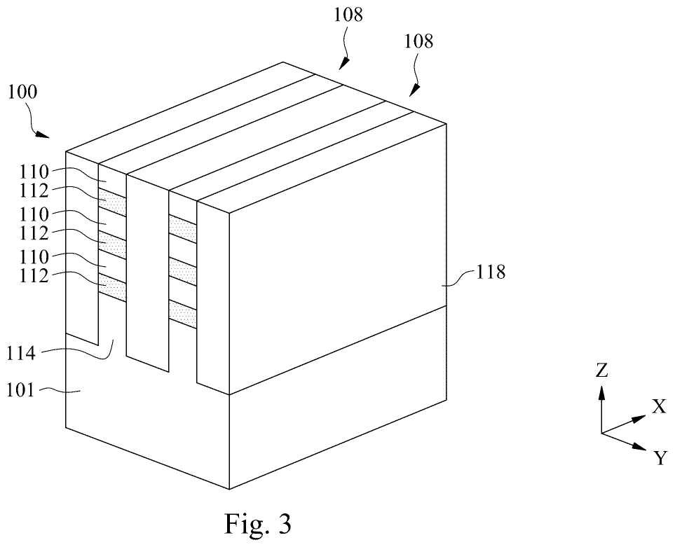

In FIG. 3, after the semiconductor strips 108 are formed, an insulating material 118 is formed over the substrate 101. The insulating material 118 fills the trenches 116 between neighboring semiconductor strips 108 until the semiconductor strips 108 are embedded in the insulating material 118. Then, a planarization operation, such as a chemical mechanical polishing (CMP) method and/or an etch-back method, is performed such that the top of the semiconductor strips 108 is exposed. The insulating material 118 may be made of silicon oxide, silicon nitride, silicon oxynitride (SiON), SiOCN, SiCN, fluorine-doped silicate glass (FSG), a low-K dielectric material (k-value less than about 3.5), or any suitable dielectric material. The insulating material 118 may be formed by any suitable method, such as flowable CVD (FCVD), low-pressure chemical vapor deposition (LPCVD), or plasma-enhanced CVD (PECVD).

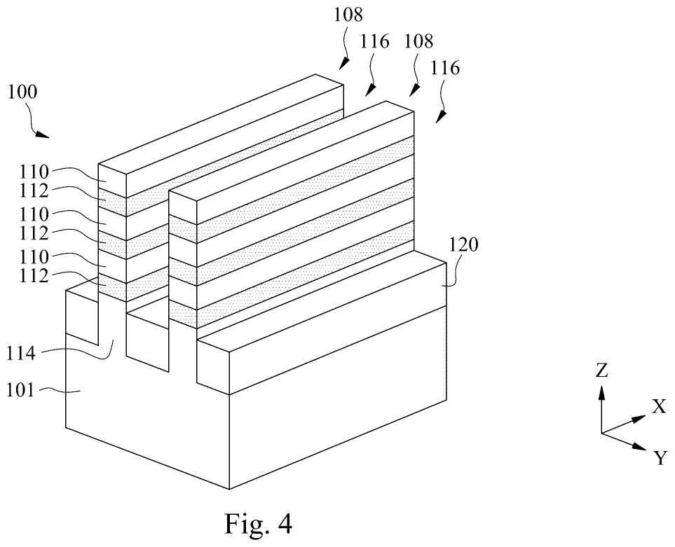

In FIG. 4, the insulating material 118 is recessed to form isolation regions 120. The recess of the insulating material 118 exposes portions of the semiconductor strips 108 and the substrate 101. The recess of the insulating material 118 reveals the trenches 116 between the neighboring semiconductor strips 108. The isolation regions 120 may be formed using a suitable process, such as a dry etch process, a wet etch process, or a combination thereof. Top surfaces of the isolation regions 120 may be level with or below top surfaces of the fins 114 and in contact with the fins 114.

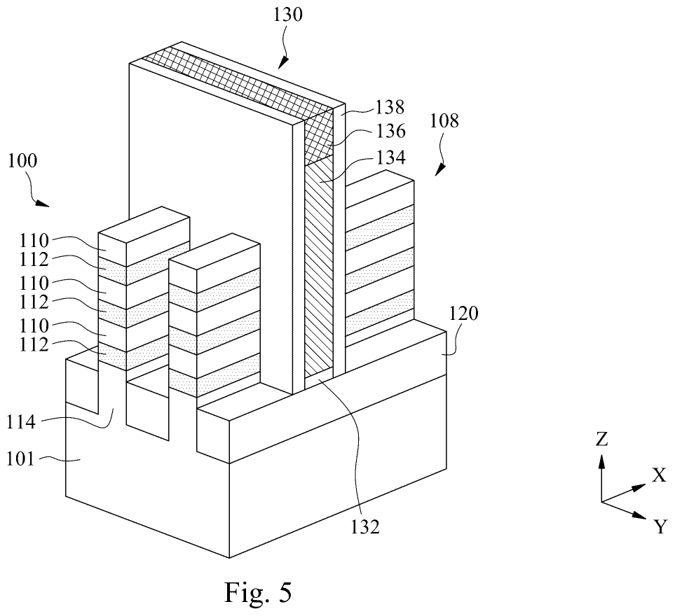

In FIG. 5, one or more dummy gate structures 130 (only one is shown) are formed over the semiconductor device 100. The dummy gate structures 130 are formed over a portion of the semiconductor strips 108. Each dummy gate structure 130 may include a dummy gate dielectric 132, a dummy gate electrode 134, and a hard mask 136. The dummy gate dielectric 132, the dummy gate electrode 134, and the hard mask 136 may be formed by sequentially depositing blanket layers of the dummy gate dielectric 132, the dummy gate electrode 134, and the hard mask 136, and then patterning those layers into the dummy gate structures 130. The dummy gate structure 130 may have a longitudinal direction (e.g., the Y-direction in FIG. 5) substantially perpendicular to the longitudinal directions of the semiconductor strips 108 (e.g., the X-direction in FIG. 5). The dummy gate structure 130 may land on the isolation regions 120 and cross over a single one or a plurality of the semiconductor strips 108.

The dummy gate dielectric 132 may include one or more layers of dielectric material, such as a deposited oxide-based material (e.g., silicon oxide) or a material oxidized from the substrate 101. The dummy gate electrode 134 may include silicon such as polycrystalline silicon or amorphous silicon. The hard mask 136 may include one or more dielectric layers. For example, the hard mask 136 may be a combination of an oxide layer and a nitride layer.

Gate spacers 138 are then formed on sidewalls of the dummy gate structure 130. The gate spacers 138 may be formed by conformally depositing one or more layers for the gate spacers 138 and anisotropically etching (e.g., RIE) the one or more layers. Dielectric materials such as silicon nitride, silicon oxide, silicon carbide, silicon oxide, silicon carbonitride, silicon oxynitride, silicon oxycarbonitride, combinations thereof, or the like, may be used for the gate spacers 138.

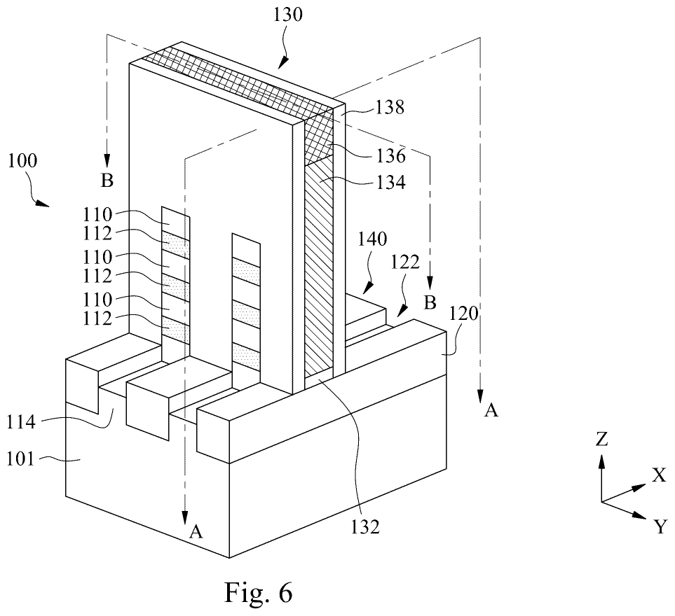

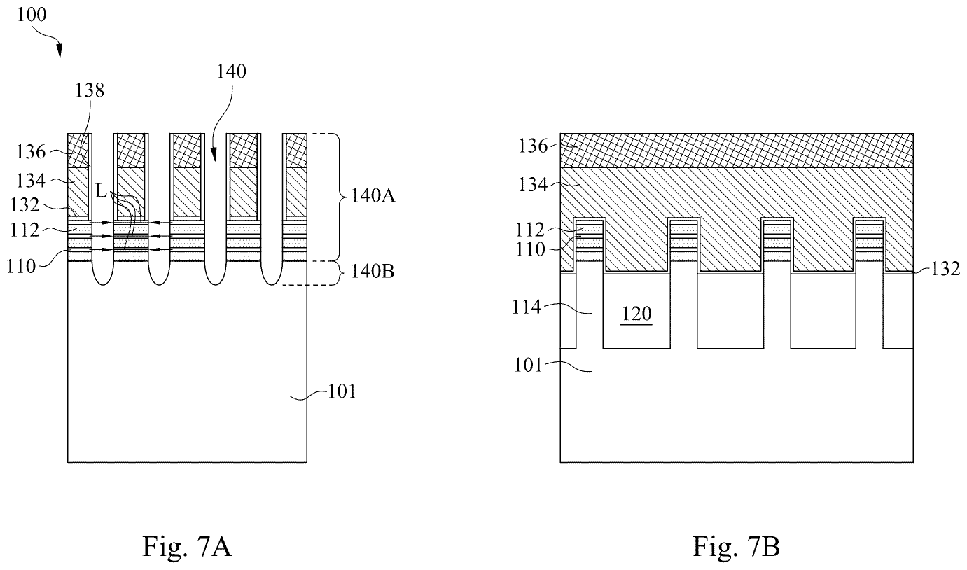

In FIG. 6, first openings 140 are formed in the semiconductor strips 108, the fins 114, and the substrate 101, in accordance with some embodiments. The first openings 140 may be formed by removing at least portions of the semiconductor strips 108 and the substrate 101 that are not protected by the gate spacers 138 and the dummy gate structures 130. As such, the first openings 140 may be formed between neighboring dummy gate structures 130 in the X-direction as illustrated in FIG. 6 (or the cross-sectional view illustrated in FIG. 7). The first openings 140 may be recessed to below the top surfaces of the isolation regions 120, although the first openings also can be recessed to level with or above the top surfaces of the isolation regions 120. The first openings 140 may be formed by an etch process, either isotropic or anisotropic etch process, and the etch process may be selective with respect to one or more crystalline planes of the substrate 101. The etch process may be a dry etch, such as a RIE, NBE, or the like, or a wet etch. The etchant from the etch process may include CH₂F₂, C₂F₆, and/or CF₄, with or without HBr, Cl₂, and/or O₂, or the like.

FIGS. 7A and 7B are cross-sectional views of the semiconductor device 100 taken in directions along cross-section A-A and cross-section B-B of FIG. 6, respectively. A plurality of dummy gate structures 130, a plurality of semiconductor strips 108 and more detail elements are illustrated in the cross-sectional views, in accordance with some embodiments. Throughout the description, the figures with figure numbers including “A” are obtained from the reference cross-section A-A in FIG. 6, and Figure numbers including “B” are obtained from the reference cross-section B-B in FIG. 6.

In FIGS. 7A and 7B, the first openings 140 extend through the stack of the first nanostructures 110 and the second nanostructures 112, and into the substrate 101. In some embodiments, the first openings 140 have an extended depth, such as at least about 2 times greater than the height of the stack of the first nanostructures 110 and the second nanostructures 112. In some embodiments, the first openings 140 include upper portions 140A at least extending through all the first nanostructures 110 to expose all the first nanostructures 110. In some embodiments, the upper portions 140A also extend to below the bottom of the bottommost second nanostructure 112. It is appreciated that although dry etch is an anisotropic etch and can create substantial vertical sidewalls for upper portions of openings, the openings created by the dry etch may have gradually narrowed widths toward the bottom of the openings. With forming an extended depth for the first openings 140, upper portions 140A of the first openings 140 can have substantially vertical sidewall profiles and allow each of the first nanostructures 110 between the first openings 140 to have a fixed length L. As will be discussed in detail below, because each of the first nanostructures 110 has a substantially same length, the current paths through each of the first nanostructures 110 would be substantially the same and can therefore provide transistor structures a sharp on-off transition. In some embodiments, each of the first openings 140 also includes a lower portion 140B below and connected to the upper portion 140A. The lower portion 140B of the first openings 140 may have gradually narrowed widths toward the bottom of the first openings 140, such as having a parabolic or triangle shape in the cross-sectional view. In some embodiments, a ratio of a height of the upper portion 140A to a height of the lower portion 140B is about 5 to about 15. The extended depth of first openings 140 may be achieved by increasing etching time and/or increasing the plasma bias.

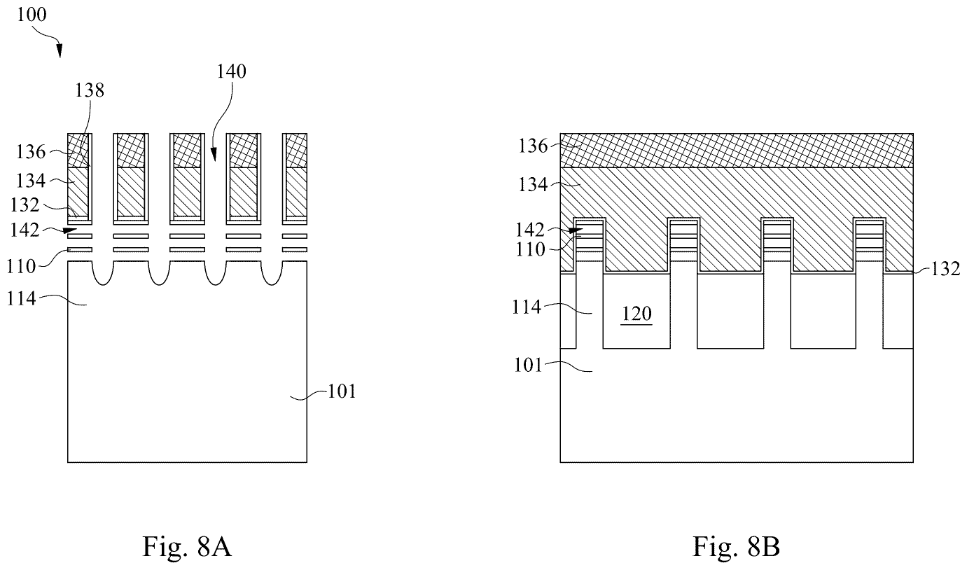

In FIGS. 8A and 8B, the second nanostructures 112 exposed by the first openings 140 are etched to form second openings 142, in accordance with some embodiments. That is, the second openings 142 may be space that was occupied by the second nanostructures 112, including the space between the adjacent first nanostructures 110 and between the bottommost first nanostructure 110 and the substrate 101. While using etchants selective to etch the second semiconductor material of the second nanostructures 112, the first nanostructures 110 and the substrate 101 remain relatively unetched. In an embodiment that the second semiconductor material includes, e.g., SiGe, an etch process using a hydroxide etchant, such as tetramethylammonium hydroxide (TMAH), ammonium hydroxide (NH₄OH), or the like, is used.

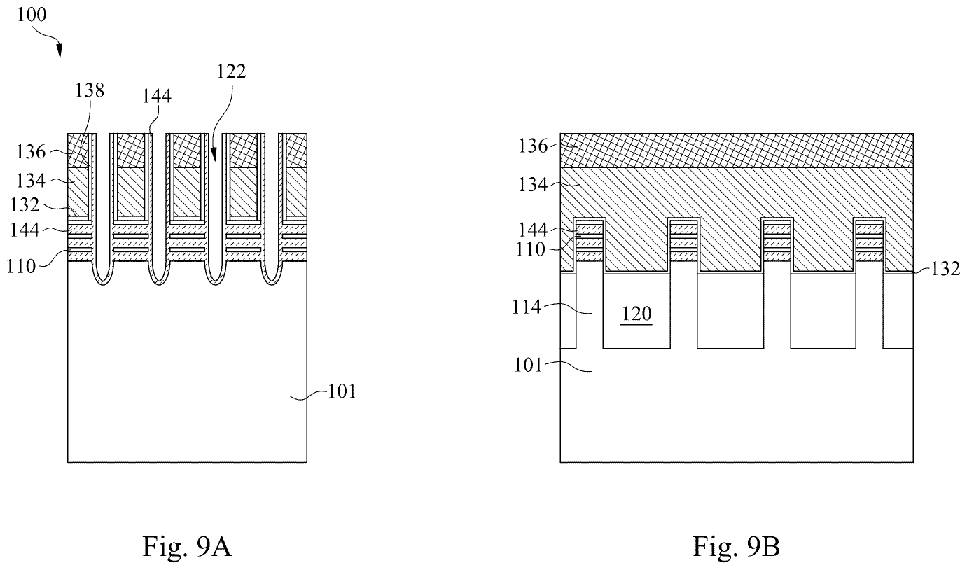

In FIGS. 9A and 9B, an insulating layer 144 is deposited in the first openings 140 and the second openings 142, in accordance with some embodiments. In some embodiments, given the size differences between the first openings 140 and the second openings 142, the insulating layer 144 may substantially or completely fill the second openings 142 and form a conformal layer in the first openings 140. The insulating layer 144 may include an oxide-containing material, such as silicon oxide, silicon oxynitride, silicon carbonitride, fluorine-doped silicate glass (FSG), a low-K dielectric material, or any suitable dielectric material. In some embodiments, the insulating layer 144 includes a material similar to those of the isolation regions 120. The insulating layer 144 may be formed by any suitable depositing method, such as FCVD, ALD, PECVD, LPCVD, combinations thereof, or the like.

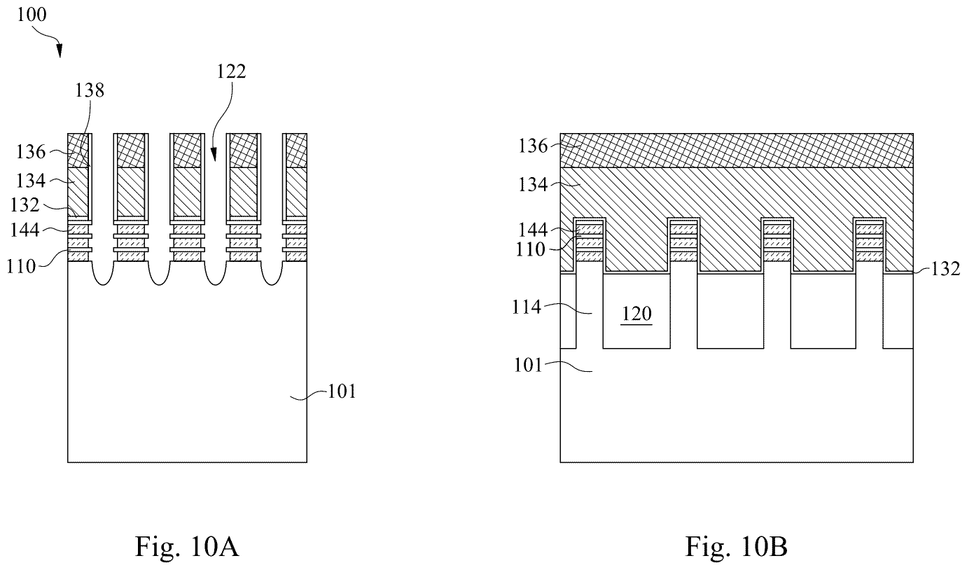

In FIGS. 10A and 10B, an etch process is performed to remove the insulating layer 144 in the first openings 140 and partially recess the insulating layer 144 in the second openings 142 (FIG. 8A), in accordance with some embodiments. The etch process may use etchants selective to etch the insulating layer 144, and the first nanostructures 110 and the substrate 101 may remain relatively unetched. The etch process may be an isotropic etch process. In some embodiments, the isotropic etch process is performed for a sufficient time to remove the insulating layer 144 in the first openings 140 and laterally recess the insulating layer 144 in the second openings 142. Accordingly, the insulating layer 144 is substantially or completely removed in the first openings 140. In an embodiment in which the insulating layer 144 remains in the first openings 140 after the isotropic etch process, a further anisotropic process may be performed to substantially or completely remove the insulating layer 144 in the first openings 140.

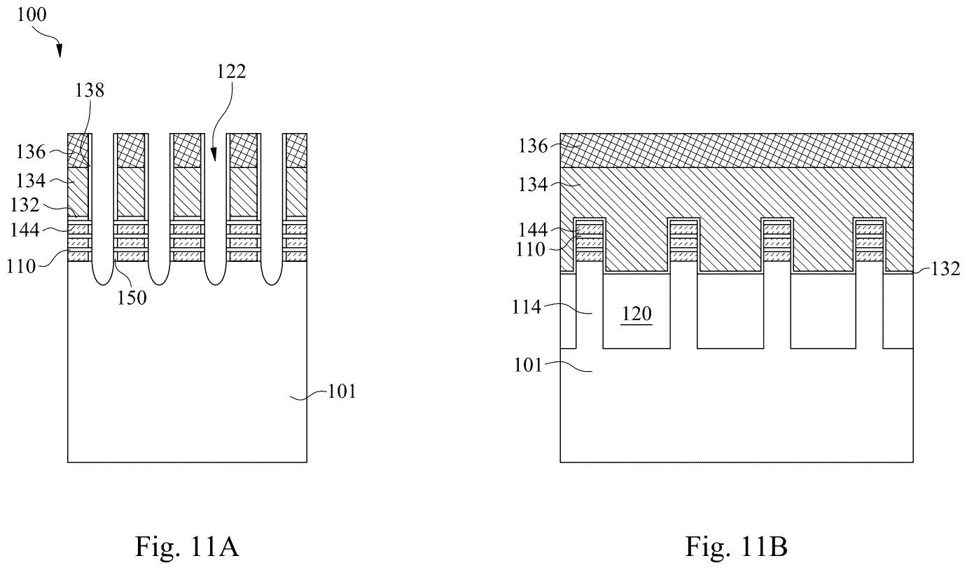

In FIGS. 11A and 11B, inner spacers 150 are formed in the lateral recesses and on the sidewalls of the insulating layer 144, in accordance with some embodiments. The inner spacers 150 may act as isolation features between subsequently formed source/drain regions and a gate structure. As will be discussed in greater detail below, the source/drain regions will be formed in the first openings 140, and the insulating layer 144 will be replaced with gate structures.

In some embodiments, an inner spacer layer is deposited by a conformal deposition process, such as CVD, ALD, or the like. The inner spacer layer may include a material such as silicon nitride or silicon oxynitride, although any suitable material, such as a low-K dielectric material, may be utilized. The inner spacer layer may then be anisotropically etched to form the inner spacers 150, such as by RIE, NBE, or the like, using the gate spacers 138 as a mask. Although outer sidewalls of the inner spacers 150 are illustrated as being flush with sidewalls of the first nanostructures 110 in FIG. 11A, the outer sidewalls of the inner spacers 150 may extend beyond or be recessed from sidewalls of the first nanostructures 110. Moreover, although the outer sidewalls of the inner spacers 150 are illustrated as being straight in FIG. 11A, the outer sidewalls of the inner spacers 150 may be concave or convex.

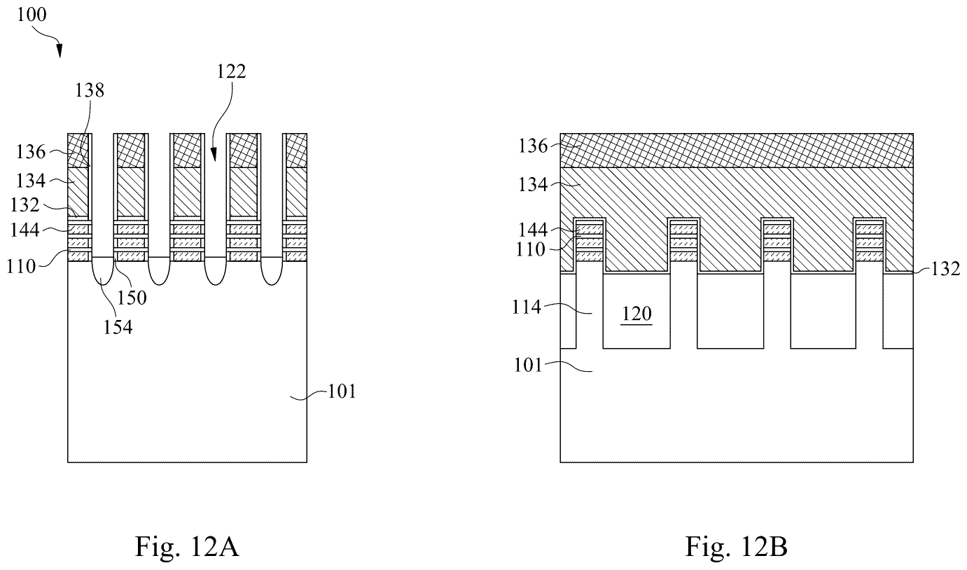

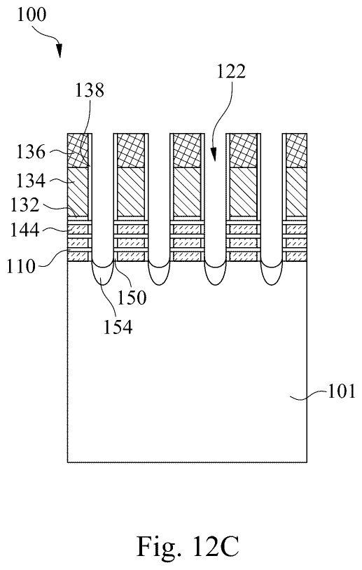

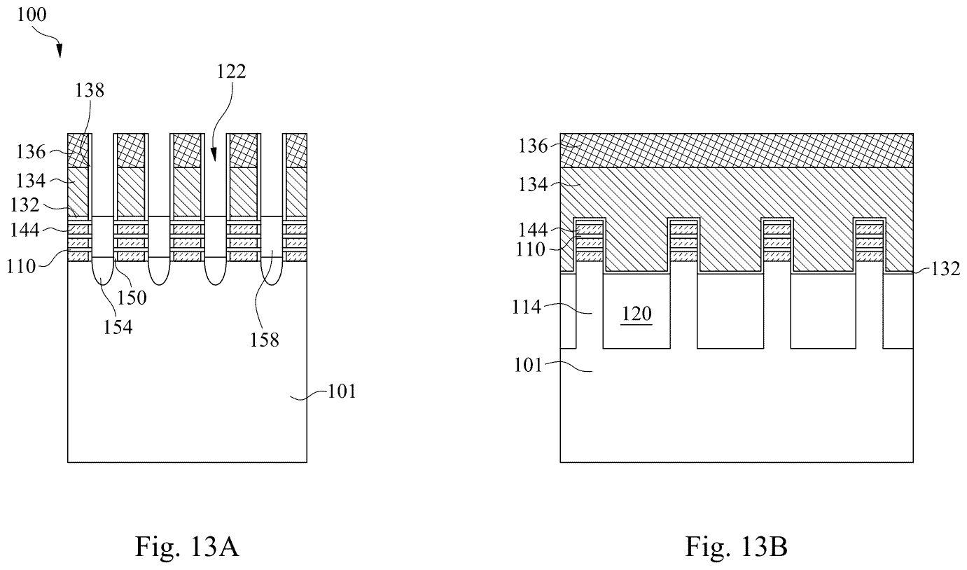

In FIGS. 12A and 12B, a dielectric filling 154 is formed in the first openings 140, in accordance with some embodiments. The dielectric filling 154 may be formed, for example, by depositing a dielectric layer having a relatively thick thickness on the bottom of the first openings 140 and relatively a thinner thickness on the sidewalls of the first openings 140, and a trimming etch process may then be performed to remove the dielectric layer on the sidewalls of the first openings 140. The deposition of the dielectric layer may include FCVD, PECVD, LPCVD, combinations thereof, or the like. The trimming etch process may be a wet etch, a dry etch with a suitable inclined angle, or a combination thereof. In some embodiments, the processes of depositing the dielectric layer and trimming etch processes may be repeated to allow the dielectric filling 154 to have a sufficient thickness at the bottom of the first openings 140. The dielectric filling 154 may at least cover the exposed surfaces of the first openings 140 below the bottommost insulating layer 144 to isolate the subsequently formed source/drain regions 158 (FIG. 13A) from the substrate 101. Since the first openings 140 are deeply extended into the substrate 101, the dielectric filling 154 may effectively reduce or prevent leakage or cross-talk between adjacent epitaxial source/drain regions (FIG. 13A).

The upper surface of the dielectric filling 154 may be a planar surface, a convex surface, or a concave surface. In some embodiments, as illustrated in FIG. 12C, the upper surface of the dielectric filling 154 may be a concave surface to allow more volume of the source/drain regions 158 to be formed in the first openings 140, which may provide improved electrical performance. The upper surface of the dielectric filling 154 may vertically overlap the bottommost inner spacers 150 (e.g., between the bottom of the bottommost first nanostructure 110 and the top of the fin 114/substrate 101). The dielectric filling 154 may not be in physical contact with the first nanostructures 110.

In FIGS. 13A and 13B, source/drain regions 158 are formed in the first openings 140 and over the dielectric filling 154, in accordance with some embodiments. In this disclosure, a source region and a drain region are interchangeably used, and the structures thereof are substantially the same. Furthermore, source/drain region(s) may refer to a source or a drain, individually or collectively, depending upon the context. The source/drain regions may exert stress on the first nanostructures 110, thereby improving device performance. The source/drain regions 158 may be made of one or more layers of Si, SiP, SiC and SiCP for n-channel FETs or one or more layers of Si, SiGe, Ge for p-channel FETs. For p-type field effect transistors (PFETs), p-type impurities, such as boron, boron fluoride, indium, or the like, may be included in the source/drain regions 158. For n-type field effect transistors (NFETs), n-type impurities, such as phosphorus, arsenic, antimony, or the like, may be included in the source/drain regions 158. The source/drain regions 158 may be formed by an epitaxial growth method using such as, CVD, ALD, MBE, combinations therefore, or the like, and can also be referred to as epitaxial source/drain regions 158. In some embodiments, the impurities may be in situ doped when epitaxially depositing the source/drain regions 158. The source/drain region 158 may have an impurity concentration of between about 1×10¹⁹ atoms/cm³ and about 1×10²¹ atoms/cm³. In some embodiments, the source/drain regions 158 grow to form facets, which may correspond to crystalline planes of the material used for the substrate 101.

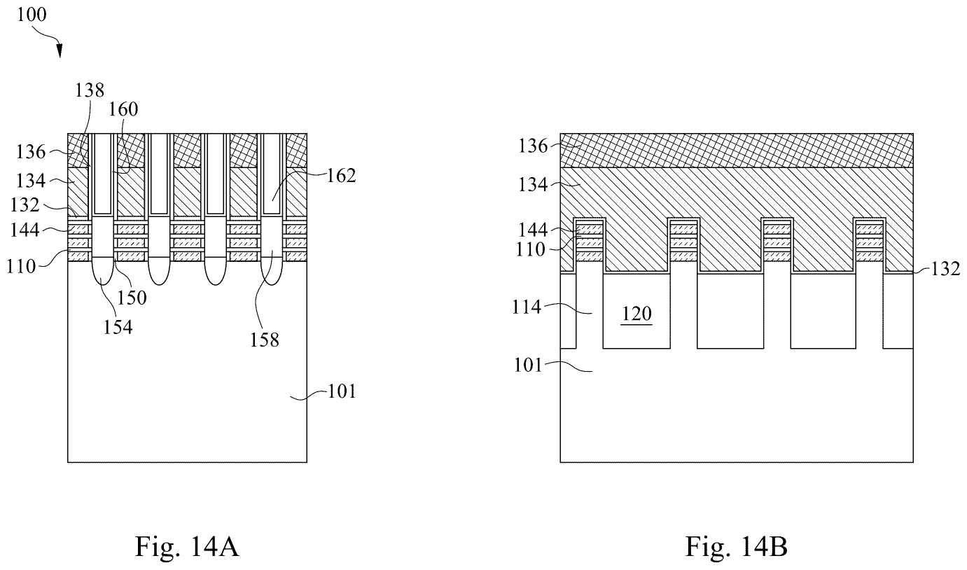

In FIGS. 14A and 14B, a contact etch stop layer (CESL) 160 is conformally formed on the exposed surfaces of the semiconductor device 100, in accordance with some embodiments. The CESL 160 covers the isolation regions 120, the source/drain regions 158, and the sidewalls of the gate spacers 138. The CESL 160 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 162 is formed on the CESL 160 over the semiconductor device 100. The materials for the first ILD layer 162 may include compounds including Si, O, C, and/or H, such as silicon oxide, SiCOH, SiOC, PSG, BSG, BPSG, combinations thereof, or the like. Organic materials, such as polymers, may also be used for the first ILD layer 162. The first ILD layer 162 may be deposited by FCVD, PECVD, or other suitable deposition techniques. In some embodiments, after the first ILD layer 162 is deposited, a thermal process is performed to cure the first ILD layer 162. After the first ILD layer 162 is formed, a planarization operation, such as CMP, is performed to level the top surface of the first ILD layer 162 with the top surfaces of dummy gate electrodes 134 or the hard masks 136. In some embodiments in which the hard masks 136 remain, the planarization process levels the top surface of the first ILD layer 162 with the top surfaces of the hard masks 136 and the gate spacers 138. In some embodiments, top surfaces of the dummy gate electrodes 134, the gate spacers 138, and the first ILD layer 162 are level within process variations after the planarization process. In such embodiments, the top surfaces of the dummy gate electrodes 134 are exposed through the first ILD layer 162.

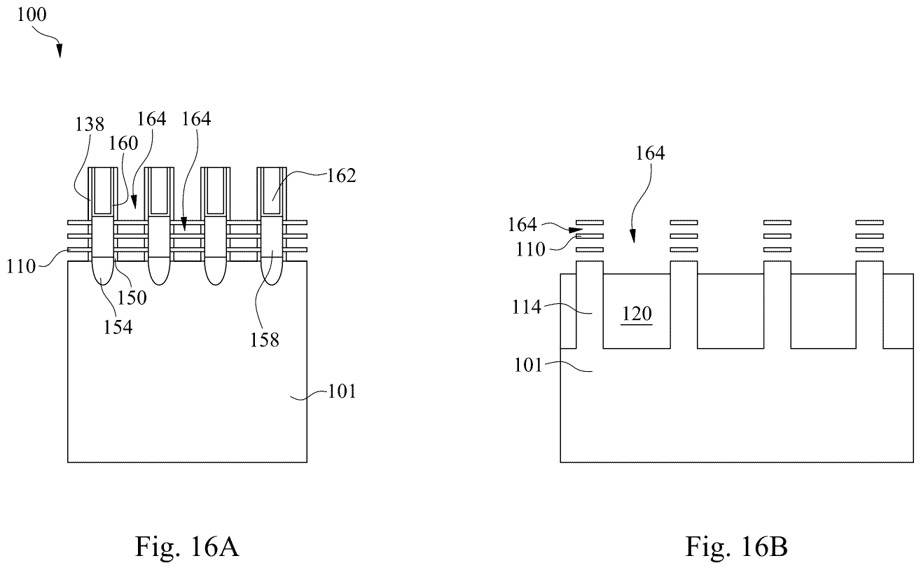

In some embodiments, an optional first capping layer (not shown) is formed over the first ILD layer 162. The formation of the first capping layer may include recessing the first ILD layer 162 between the dummy gate electrodes 154 and filling the recession with the first capping layer created by recessing process. Filling the recession with the first capping layer may be achieved by any suitable deposition process, such as CVD, PECVD, ALD, or other suitable methods. In some embodiments, a planarization process is then performed to remove excess portions of the first capping layer over the dummy gate electrodes 134, so an upper surface of the first capping layer is level with the upper surfaces of the dummy gate electrodes 134 or the hard masks 136 (if exists). In some embodiments, the first capping layer includes silicon nitride, silicon oxynitride, silicon carbide, silicon carbonitride, silicon oxycarbonitride, a combination thereof, or the like. The first capping layer may protect the first ILD layer 162 not being damaged in the process of removing the insulating layer 144 as illustrated in FIGS. 16A and 16B.

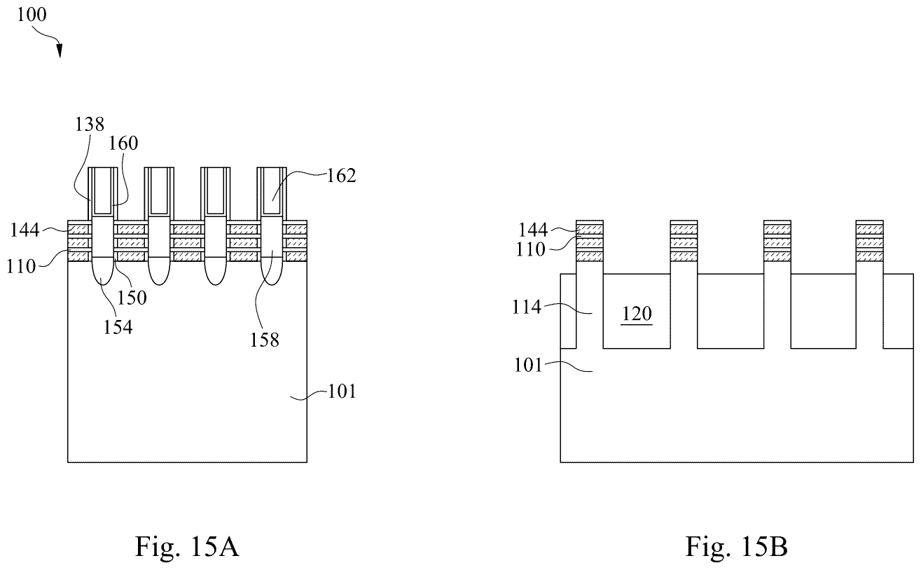

In FIGS. 15A and 15B, the dummy gate electrodes 134 and the hard masks 136 (if exist) are removed. In some embodiments, the dummy gate dielectrics 132 are also removed after the dummy gate electrodes 134 are removed. The hard masks 136, the dummy gate electrodes 134 and the dummy gate dielectrics 132 may be removed by one or more etch processes. For example, an etch process may be performed by etching the hard masks 136 using the dummy gate electrodes 134 as an etch stop, etching the dummy gate electrodes 134 using the dummy gate dielectrics 132 as an etch stop, and the dummy gate dielectrics 132 are then removed by another etch process. In some embodiments, the etch process for etching the dummy gate electrodes 134 and the dummy gate dielectrics 132 may include using reaction gas(es) that selectively etch the dummy gate electrodes 134 and the dummy gate dielectrics 132 at a faster rate than the first ILD layer 162 or the gate spacers 138. As illustrated in FIG. 15B, after the dummy gate dielectrics 132 and the dummy gate electrodes 134 are removed, the insulating layer 144 is exposed.

In FIGS. 16A and 16B, the insulating layer 144 is removed, in accordance with some embodiments. The insulating layer 144 may be removed by an isotropic etch process, such as by a wet etching containing an etchant containing a dilute HF or other suitable etchants. The removal of the hard masks 136, the dummy gate electrodes 134, the dummy gate dielectrics 132, and the insulating layer 144 forms third openings 164 between the gate spacers 138 and between the first nanostructures 110. In some embodiments, the processes related to the insulating layer 144, such as the processes illustrated in FIGS. 8A-11B can be omitted so the second nanostructures 112 still remain and not replaced with the insulating layer 144. In such embodiments, the third openings 164 are formed by removing the second nanostructures 112, and features such as the inner spacers 150 and the dielectric filling 154 as illustrated in FIGS. 12A-15B are still formed and located at the positions as shown in FIG. 16A.

In some embodiments, before the insulating layer 144 is removed, an optional second capping layer (not shown) is formed over the isolation regions 120. The formation of the second capping layer may include depositing a dielectric material over the upper surfaces of the isolation regions 120 and exposed surfaces of the first nanostructures 110 and the insulating layer 144. In some embodiments, by adjusting suitable deposition parameters or depending on the deposition methods (e.g., FCVD), a thickness of the dielectric material over the upper surfaces of the isolation regions 120 may be greater than a thickness of the dielectric material over the exposed surfaces of the first nanostructures 110 and the insulating layer 144. An etch process may then be performed to remove the dielectric material of over the exposed surfaces of the first nanostructures 110 and the insulating layer 144 while some of the dielectric material on the upper surfaces of the isolation regions 120 may remain to form the second capping layer. The etch process may include a wet etch process, a dry etch process, or a combination thereof. In some embodiments, the second capping layer includes silicon nitride, silicon oxynitride, silicon carbide, silicon carbonitride, silicon oxycarbonitride, a combination thereof, or the like. The second capping layer may protect the isolation regions 120 not being damaged in the process of removing the insulating layer 144.

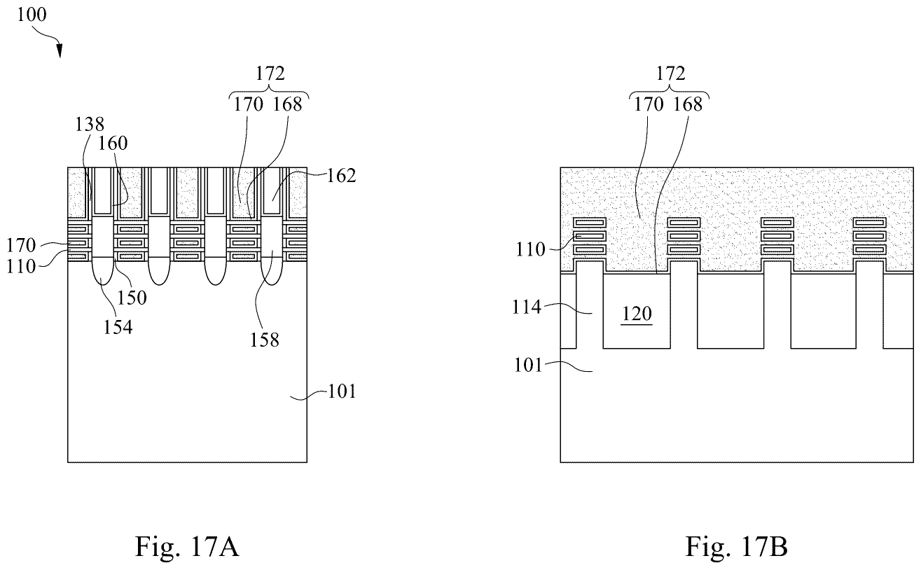

In FIGS. 17A and 17B, gate dielectric layers 168 and gate electrodes 170 are formed for replacement gates. The gate dielectric layers 168 are deposited conformally in the third openings 164. The gate dielectric layers 168 may be formed on top surfaces and sidewalls of the substrate 101 and on exposed surfaces of the first nanostructures 110, In some embodiments, the gate dielectric layers 168 are also deposited on top surfaces of the first ILD layer 162 (or the second capping layer, if exists), the CESL 160, the gate spacers 138, and the isolation regions 120. In some embodiments, the gate dielectric layers 168 include one or more layers of a dielectric material, such as silicon oxide, silicon nitride, or high-K dielectric material, other suitable dielectric material, and/or combinations thereof. Examples of high-K dielectric material include HfO, HfSiO, HfSiON, HfTaO, HfTiO, HfZrO, zirconium oxide, aluminum oxide, titanium oxide, hafnium oxide-alumina (HfO—AlO) alloy, other suitable high-K dielectric materials, and/or combinations thereof. The gate dielectric layers 168 may be formed by CVD, ALD, or any suitable deposition techniques.

The gate electrodes 170 are deposited over the gate dielectric layer 168, respectively, and fill the remaining portions of the third openings 164. The gate electrodes 170 may include a metal-containing material such as titanium nitride, titanium oxide, tantalum nitride, tantalum carbide, cobalt, ruthenium, aluminum, tungsten, combinations thereof, or multi-layers thereof. Although single-layer gate electrodes 170 are illustrated in FIGS. 17A and 17B, the gate electrodes 170 may comprise any number of liner layers, any number of work function tuning layers, and a fill material. The gate electrodes 170 may be formed by CVD, ALD, electro-plating, or other suitable deposition techniques. After filling the third openings 164, excess materials of the gate dielectric layers 168 and the gate electrodes 170 over the top surface of the first ILD layer 162 are then removed by a planarization process, such as CMP, until the top surfaces of the first ILD layer 162 are exposed. The remaining portions of the gate electrodes 170 and the gate dielectric layers 168 thus form replacement gate structures of the semiconductor device 100. The gate electrodes 170 and the gate dielectric layers 168 may be collectively referred to as gate structures 172. The gate structures 172 may surround channels (i.e., the first nanostructures 110) of the semiconductor device 100.

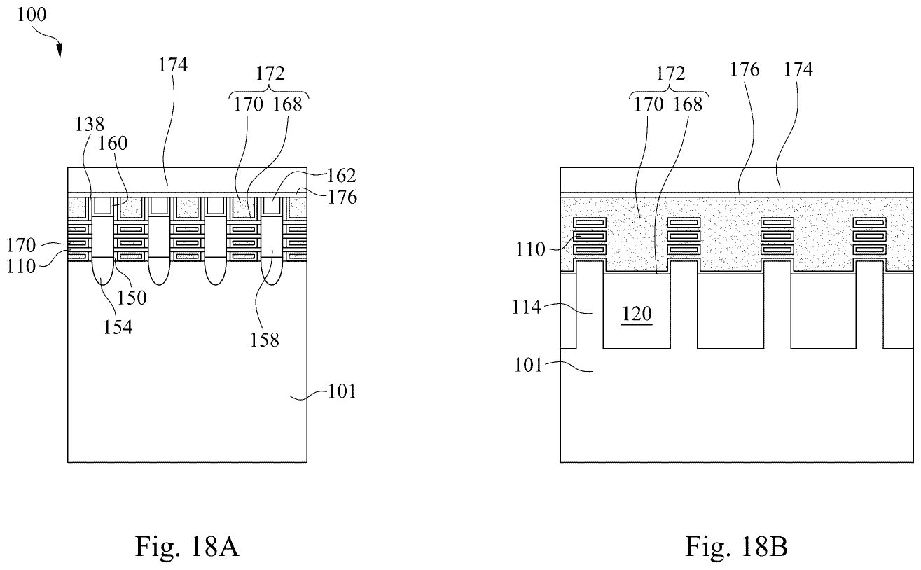

As further illustrated by FIGS. 18A and 18B, a second ILD layer 174 is deposited over the first ILD layer 162. In some embodiments, the second ILD layer 174 is formed of a dielectric material similar to those of the first ILD layer 162 and is formed by a method similar to those used for the first ILD layer 162. In some embodiments, a CESL 176 is also formed before forming the second ILD layer 174. The CESL 176 may include a material similar to those of the CESL 160 and may be formed using methods similar to those used for the CESL 160.

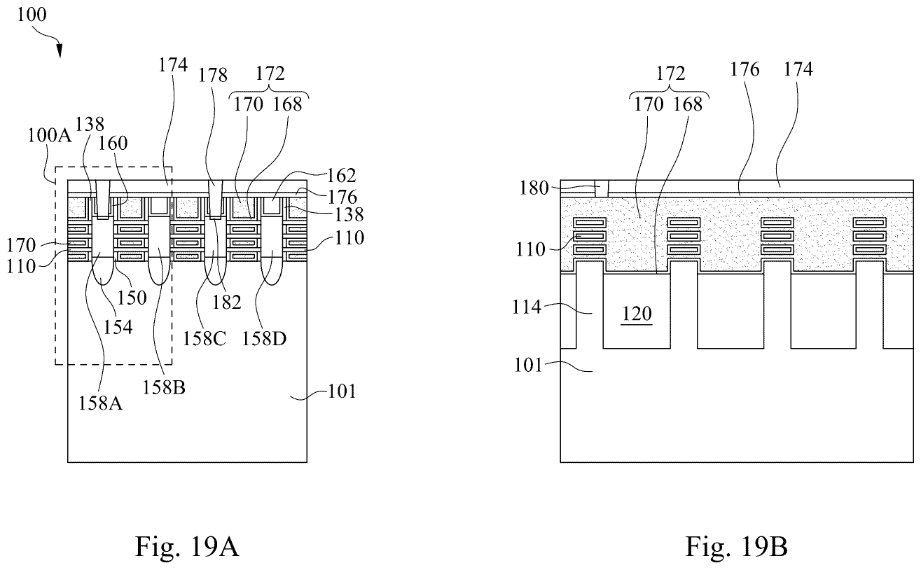

In FIGS. 19A and 19B, contacts 178 and contacts 180 are formed in the first ILD layer 162 and the second ILD layer 174, in accordance with some embodiments. The contacts 178 are electrically coupled to the source/drain regions 158 and may be referred to as source/drain contacts. Because the contacts 178 are formed over the frontside 101F of the substrate 101, the contacts 178 may also be referred to as frontside contacts or frontside source/drain contacts. The contacts 180 are electrically coupled to the gate structures 172 and may be referred to as gate contacts.

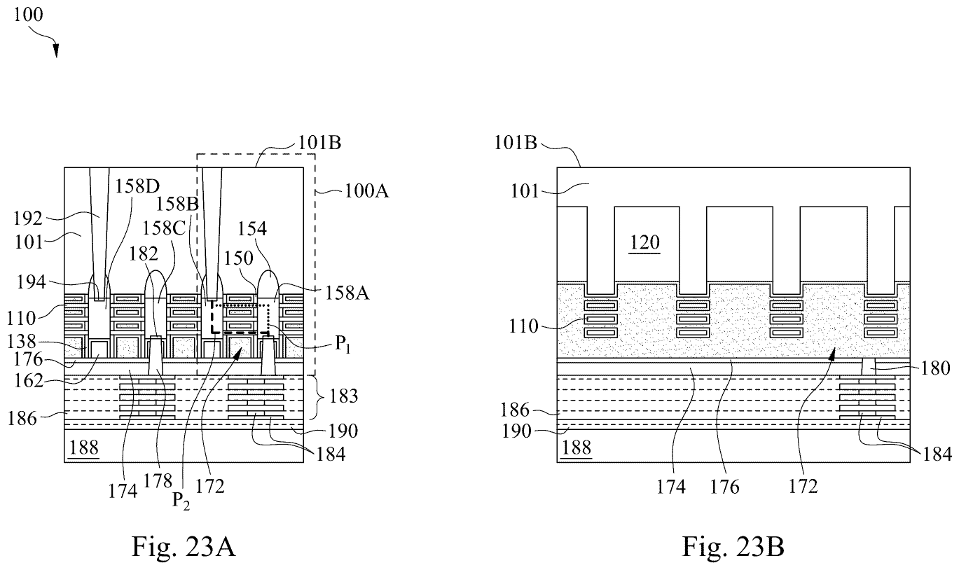

In some embodiments, the contacts 178 are electrically coupled to only one of the two adjacent source/drain regions 158. For example, the contacts 178 may extend to physically connect to front-sides of the targeted source/drain region 158. In FIG. 19A, an example of four source/drain regions 158, including a first source/drain region 158A, a second source/drain region 158B, a third source/drain region 158C, and a fourth source/drain region 158D, is illustrated, and the contacts 178 may electrically couple to the first source/drain region 158A and the third source/drain region 158C, while the second source/drain region 158B and the fourth source/drain regions 158D are covered by the first ILD layer 162 and not connected to the contacts 178. In other words, there is no conductive feature that is disposed in the first ILD layer 162 and extends to connect to the second source/drain region 158B or the fourth source/drain region 158D. As will be described in detail below, backside contacts 192 (FIG. 23A) will be formed and connect to the backside of (i.e., the side adjacent to the substrate 101) of source/drain regions 158 that are not connected to the contacts 178, such as connecting to the backsides of the second source/drain region 158B and the fourth source/drain region 158D. The first source/drain region 158A, the second source/drain region 158B, the first nanostructures 110 between the first and second source/drain regions 158A and 158B, the frontside source/drain contact 178, and the backside source/drain contact 192 may form a transistor structure 100A. In such embodiments, the first nanostructure 110A may act as channels of the transistor structure 100A, and the first source/drain region 158A and the second source/drain region 158B may together form source/drain regions for the first nanostructures 110A. Current/signal may flow into and out through the frontside contact 178 and the backside contact 192.

In some embodiments, the formation of the contacts 178 and the contacts 180 includes etching the second ILD layer 174, the first ILD layer 162, the CESL 176, and/or the CESL 160 to form recesses exposing surfaces of the source/drain regions 158 and/or the gate structure 172, and the materials of the contacts 178 and 180 are then deposited in the recesses, in accordance with some embodiments. The recesses may be formed by etching using one or more anisotropic etch processes, such as RIE, NBE, or the like.

The contacts 178 and 180 may each comprise one or more layers, such as including a barrier layer, an adhesive layer, and a filling material over the barrier layer and/or the adhesive layer. In some embodiments, the barrier layer of the contacts 178 and 180 includes the titanium, titanium nitride, tantalum, tantalum nitride, or the like. The conductive material of the contacts 178 and 180 may be copper, a copper alloy, silver, gold, tungsten, cobalt, aluminum, nickel, or the like. In some embodiments, the contacts 178 also include silicide regions 182 in contact with the source/drain regions 158 to reduce resistance. The silicide regions 182 may be formed between the barrier layer (or the filling material) and the source/drain regions 158 by reacting the materials of the barrier layer (or the filling material) of the contacts 178 with the semiconductor materials of source/drain regions 158. Although silicide regions 182 are referred to as silicide regions, the silicide regions 182 may also be germanide regions, or germano-silcide regions. A planarization process, such as a CMP, may be performed to remove excess materials of the contacts 178 and 180 over the top surface of the second ILD layer 174.

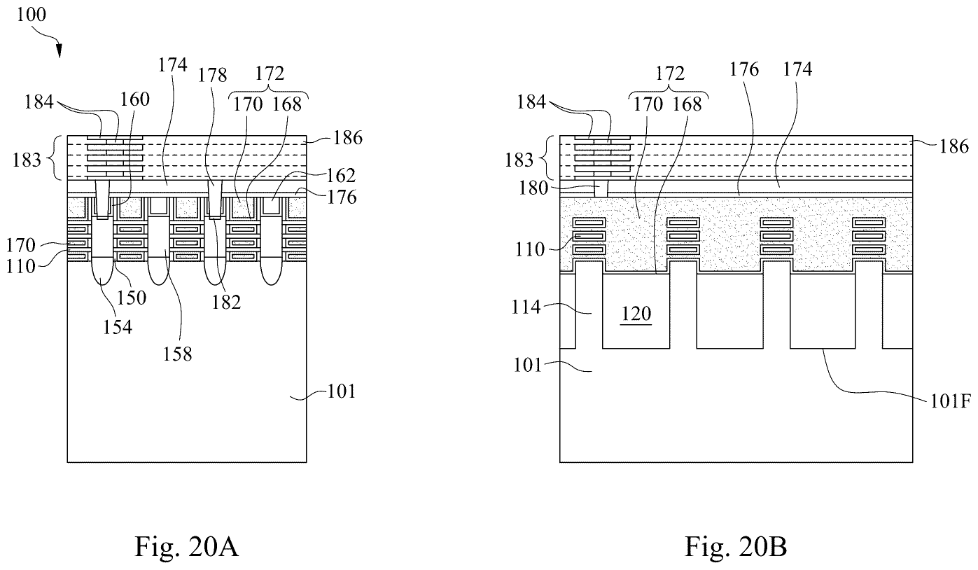

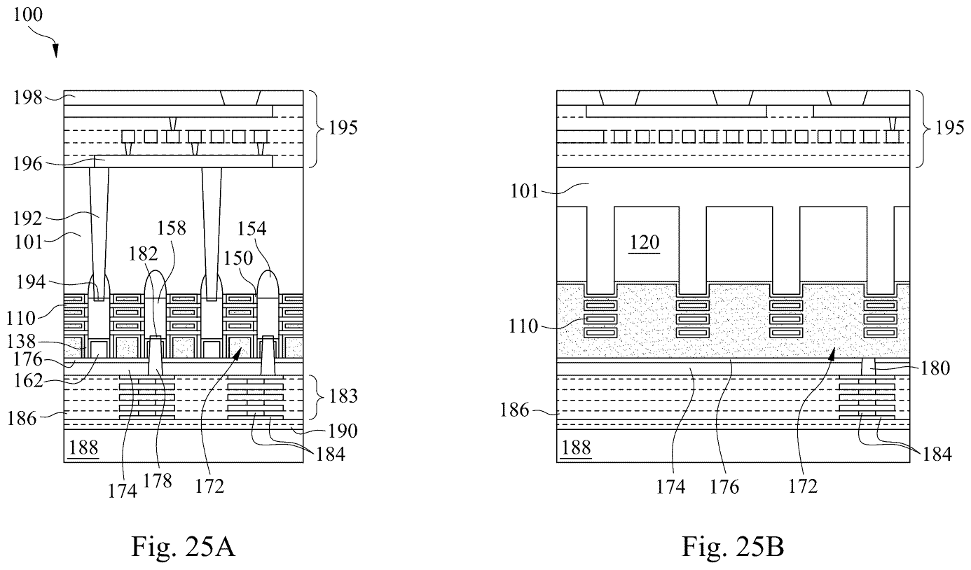

FIGS. 20A-23B and 25A-25B illustrate intermediate steps of forming a frontside interconnect structure 183 over the frontside 101F of the substrate 101 (illustrated in FIGS. 20A and 20B), backside contacts 192 in the substrate 101 (illustrated in FIGS. 23A and 23B), and a backside interconnect structure 195 over the backside 101B of the substrate 101 (illustrated in FIGS. 25A and 25B), in accordance with some embodiments. The frontside interconnect structure 183 and the backside interconnect structure 195 may each comprise conductive features that are electrically coupled to the transistor structures 100A or other transistor structures. As noted above, the backside contacts 192 may be connected to the source/drain regions 158 that are not connected to the frontside source/drain contacts 178, such as the second source/drain region 158B and the fourth source/drain region 158D as illustrated in FIG. 19A.

In FIGS. 20A and 20B, the frontside interconnect structure 183 is formed over the frontside 101F of the substrate 101, such as over the second ILD layer 174, in accordance with some embodiments. The frontside interconnect structure 183 may comprise one or more layers of conductive features 184 formed in one or more stacked dielectric layers 186. Each of the stacked dielectric layers 186 may comprise a dielectric material, such as silicon oxide, PSG, BSG, BPSG, a low-K dielectric material, combinations thereof, or the like. The dielectric layers 186 may be deposited using an appropriate process, such as CVD, PECVD, PVD, or the like.

The conductive features 184 may comprise conductive lines and conductive vias interconnecting the layers of conductive lines. The conductive vias may extend through respective ones of the dielectric layers 186 to provide vertical connections between layers of the conductive lines. The conductive features 184 may be formed through any acceptable process, such as, a single damascene process, a dual damascene process, a combination thereof, or the like. For example, the conductive features 184 may be formed using a damascene process in which a respective dielectric layer 186 is patterned utilizing a combination of photolithography and etching techniques to form trenches corresponding to the desired pattern of the conductive features 184. An optional diffusion barrier and/or optional adhesion layer may be deposited and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, combinations thereof, or the like. In an embodiment, the conductive features 184 may be formed by depositing a seed layer of copper or a copper alloy and filling the trenches by electroplating. A chemical mechanical planarization (CMP) process or the like may be used to remove excess conductive material from a surface of the respective dielectric layer 186 and to planarize surfaces of the dielectric layer 186 and the conductive features 184 for subsequent processing.

FIGS. 20A and 20B illustrate five layers of the conductive features 184 and the dielectric layers 186 in the frontside interconnect structure 183. However, it should be appreciated that the frontside interconnect structure 183 may comprise any number of conductive features 184 disposed in any number of dielectric layers 186. The frontside interconnect structure 183 may be electrically connected to the source/drain contacts 178 and the gate contacts 180. In some embodiments, the frontside interconnect structure 183 also includes bump pads at the top layer of the frontside interconnect structure 183 for external connections. The external connections may be electrically coupled to the source/drain regions 158 through the frontside interconnect structures 183 and the contacts 178.

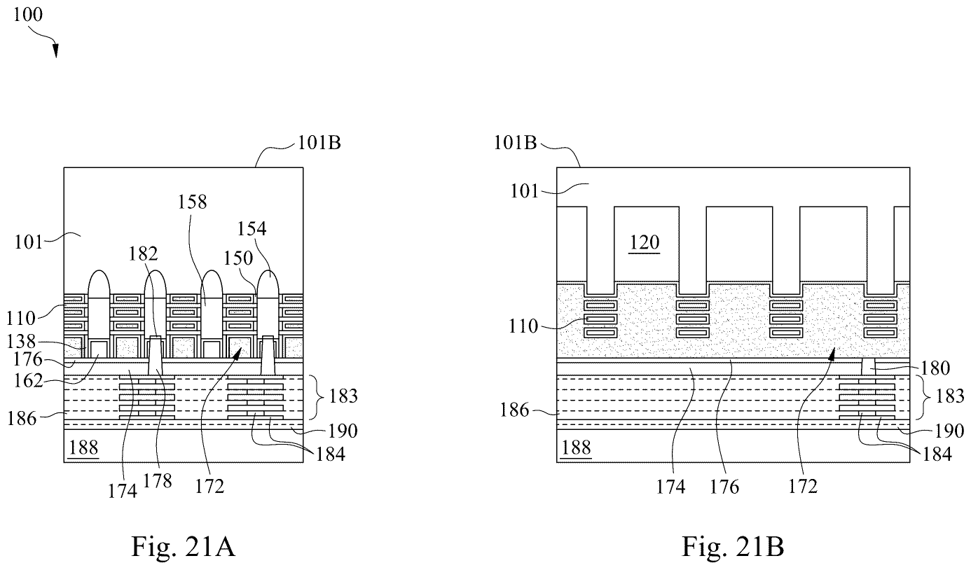

In FIGS. 21A and 21B, a carrier substrate 188 is bonded to a top surface of the frontside interconnect structure 183 through a bonding layer 190. The carrier substrate 188 may be a glass carrier substrate, a ceramic carrier substrate, a wafer (e.g., a silicon wafer), or the like. The carrier substrate 188 may provide structural support during subsequent processing steps and in the completed device.

In some embodiments, the bonding layer 190 may be a thermal-release material, which loses its adhesive property when heated, such as a light-to-heat-conversion (LTHC) release coating; an ultra-violet (UV) glue, which loses its adhesive property when exposed to UV lights; or the like. The bonding layer 190 may be dispensed as a liquid and cured. After the carrier substrate 188 is bonded to the frontside interconnect structure 183, the semiconductor device 100 may be flipped such that the backside 101B of the substrate 101 faces upwards. A thinning process is then applied to the backside 101B of the substrate 101, in accordance with some embodiments. The thinning process may include a planarization process (e.g., a mechanical grinding, a CMP, or the like), an etch-back process, a combination thereof, or the like.

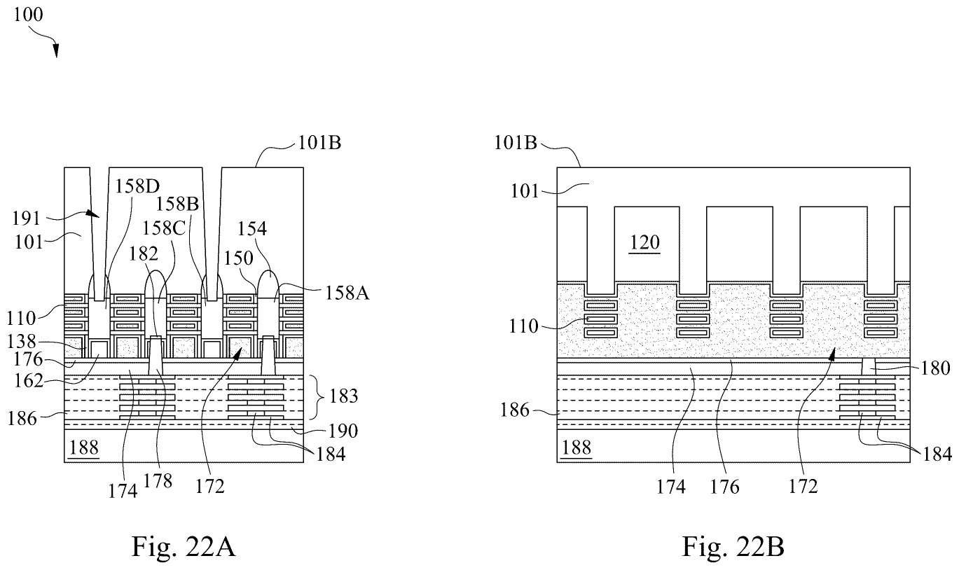

In FIGS. 22A and 22B, openings 191 for the backside contacts 192 are formed in the substrate 101, in accordance with some embodiments. The openings 191 may extend from the backside 101B of the substrate 101 and through the dielectric filling 154 to expose the backside of the source/drain regions 158. As previously discussed, the openings 191 may only extend to expose or into source/drain regions 158 that are not connected to the frontside source/drain contacts 178. For example, the openings 191 may only extend to expose or into the second source/drain region 158B and the fourth source/drain region 158D. The process for forming the openings 191 may include one or more etch processes, such as one or more anisotropic etch processes, such as RIE, NBE, or the like. For example, the process for forming the openings 191 may include a first etch process to etch through the substrate 101 from the backside 101B of the substrate and a second etch process to etch through the dielectric filling 154 to expose or extend into the source/drain regions 158.

In FIGS. 23A and 23B, backside contacts 192 are formed in the openings 191, in accordance with some embodiments. In some embodiments, the backside contacts 192 may each include one or more layers, such as a barrier layer and a filling material over the barrier layer. In some embodiments, the barrier layer of the backside contacts 192 includes titanium, titanium nitride, tantalum, tantalum nitride, or the like. The filling material of the backside contacts 192 may be copper, a copper alloy, silver, gold, tungsten, cobalt, aluminum, nickel, or the like. In some embodiments, the backside contacts 192 also include silicide regions 194 (not shown in the denoted transistor structure 100A for clarity purposes) in contact with the source/drain regions 158 to reduce resistance. The silicide regions 194 may be formed between the barrier layer (or the filling material) and the source/drain regions 158 by reacting the materials of the barrier layer (or the filling material) of the backside contacts 192 with the semiconductor materials of source/drain regions 158. A planarization process, such as a CMP, may be performed to remove excess materials of the backside contacts 192 over the backside 101B of the substrate 101.

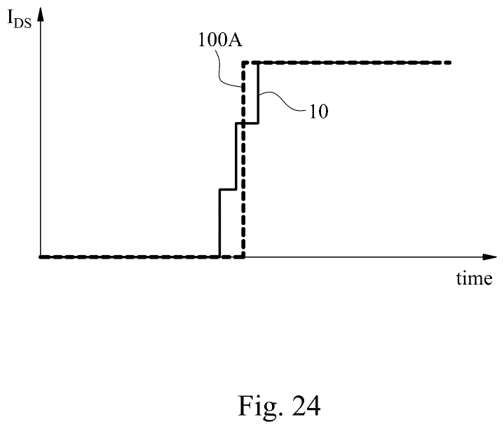

With the formation of the backside contacts 192, each transistor structure 100A may include one frontside contact 178 and one backside contact 192 disposed on opposite sides of the channels (i.e., the first nanostructures 110) in a vertical direction. Accordingly, the current paths between the frontside contact 178 and the backside contact 192 can be substantially the same, regardless of the current transmitting through which of the first nanostructures 110. In FIG. 19A, the current path P₁ (shown by a dotted line) transmitting through the topmost first nanostructures 110 (most adjacent to the first ILD layer 162) and the current path P₂ (shown by a dash line) transmitting through the bottommost first nanostructure 110 (most adjacent to the substrate 101) are shown for illustrative purposes. In some embodiments, regardless of the current transmitting through which of the first nanostructures 110, the current paths from one contact 178/192 to another contact 192/178 are the same because the total vertical transmission distances from one contact 178/192 to another contact 192/178 would be fixed by disposing the contacts 178 and 192 on opposite sides of the source/drain regions 158, and the lateral transmission distances are also fixed by forming the deeply extended first openings 140 (FIG. 7A). Thus, all the channels of the transistor structures 100A can respond to an input current or signal at the same time. FIG. 24 is a scheme illustrating the on-off transition regimes with respect to an input current for the transistor structure 100A of the present disclosure and an ordinary transistor structure 10, wherein the ordinary transistor structure 10 includes both source/drain contacts disposed on the same side of the nanostructure channels and/or nanostructure channels of different lengths. The transistor structure 100A can have a sharp on/off transition regime with respect to the input current (e.g., current drain to source, I_{DS}) because the step-like on-off transition regime of the ordinary transistor structure 10 resulting from distance variations of current paths between two source/drain contacts can be substantially eliminated.

In FIGS. 25A and 25B, a backside interconnect structure 195 is formed over the backside 101B of the substrate 101 and the exposed surfaces of the backside contacts 192, in accordance with some embodiments. The backside interconnect structure 195 includes conductive features and dielectric layers similar to the frontside interconnect structure 183. The backside interconnect structure 195 may include conductive features 196 stacked in the dielectric layers 198. The backside interconnect structures 195 are formed by methods similar to those of the frontside interconnect structures 183. For example, forming the conductive features 196 may include patterning recesses in the dielectric layer 198 using a combination of photolithography and etch processes, for example. A pattern of the recesses in the dielectric layer 198 may correspond to a pattern of the conductive features 196. The conductive features 196 are then formed by depositing a conductive material in the recesses. In some embodiments, the conductive features 196 comprise a metal layer, which may be a single layer or a composite layer comprising a plurality of sub-layers formed of different materials. In some embodiments, the conductive features 196 comprise copper, aluminum, cobalt, tungsten, titanium, tantalum, ruthenium, or the like. An optional diffusion barrier and/or optional adhesion layer may be deposited prior to filling the recesses with the conductive material. Suitable materials for the barrier layer/adhesion layer include titanium, titanium nitride, titanium oxide, tantalum, tantalum nitride, titanium oxide, or the like. The conductive features 196 may be formed using, for example, CVD, ALD, PVD, plating, or the like. The conductive features 196 are electrically coupled to the source/drain regions 158 through the backside contacts 192.

In some embodiments, the conductive features 196 include power rails, which are conductive lines that electrically connect the source/drain regions 158 to a reference voltage, a supply voltage, or the like. By placing power rails on the backside of the semiconductor device rather than on the frontside of the semiconductor die, advantages may be achieved. For example, a gate density of the semiconductor device 100 and/or an interconnect density of the frontside interconnect structure 183 may be increased. Further, the backside of the semiconductor device 100 may accommodate wider power rails, reducing resistance and increasing the efficiency of power delivery to the semiconductor device 100. For example, a width of the conductive features 196 may be at least twice a width of first level of conductive lines of the frontside interconnect structure 183.

In some embodiments, the backside interconnect structure 195 further includes bump pads at its top layer for external connections. The bump pads for external connections may also be referred to as backside input/output pads that may provide signal, supply voltage, and/or ground connections to the nanostructure transistors. The backside interconnect structures 195 may include one or more embedded passive devices (not shown), such as resistors, capacitors, inductors, or the like. The embedded passive devices may be integrated with the conductive features 196 (e.g., the power rail) to provide circuits (e.g., power circuits) on the backside of the transistor structure 100A.

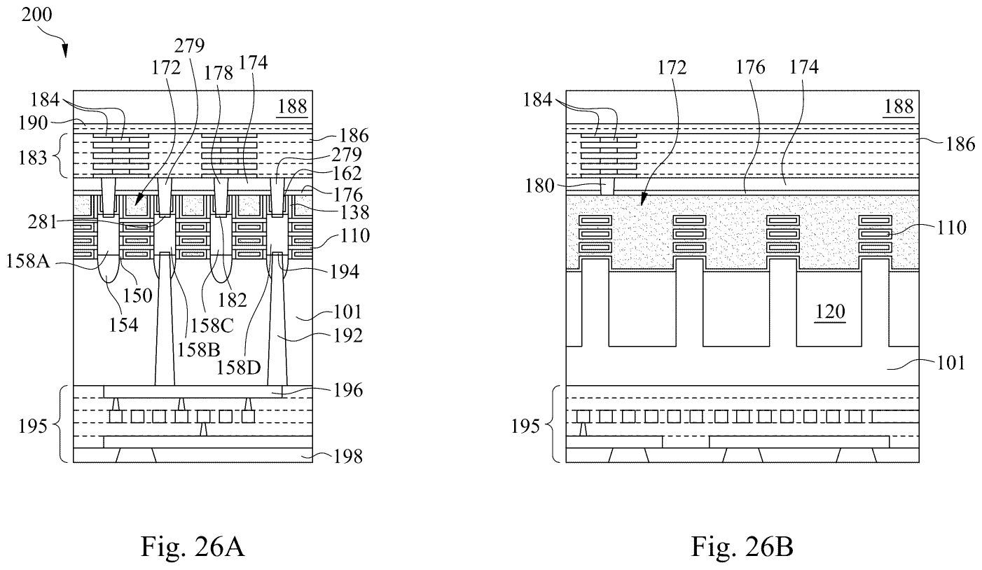

FIGS. 26A and 26B illustrate cross-sectional views of the semiconductor device 200, in accordance with some embodiments. The semiconductor device 200 is similar to the semiconductor device 100 and can be formed by processes illustrated in FIGS. 1A-23B and 25A-25B, wherein the like reference numeral refers to a like element. In FIGS. 26A and 26B, the semiconductor device 200 also includes dummy contacts 279 formed over the frontside of the substrate 101. For example, the dummy contacts 279 may be formed over and connected to the frontside of the source/drain regions 158 that are also connected to the backside contacts 192. For example, the dummy contacts 279 are formed and connected to the frontside of the second source/drain region 158B and the fourth source/drain region 158D. The top surfaces of the dummy contacts 279 may be completely sealed or covered by the dielectric layer 186 of the frontside interconnect structure 183. As such, dummy contacts 279 are not electrically and physically coupled to the conductive features 184 of the frontside interconnect structure 183, and the existence of the dummy contacts 279 would not substantially affect the current paths between the frontside contacts 178 and the backside contacts 192. The dummy contacts 279 may be formed together with the backside contacts 178 in a same process, such as in the processes illustrated in FIGS. 19A and 19B. The dummy contacts 279 may have the same structure and materials as the contacts 178. As an example, the dummy contacts 279 may have a same height as the contacts 178. In some embodiments, the dummy contacts 279 also include silicide regions 281 in contact with the source/drain regions 158. The formation of the dummy contacts 279 may facilitate the manufacturing processes. For example, the semiconductor device 200 may have a uniform pattern density of contacts 279, 178, and 180, which can help reduce the dishing resulting from a planarization process, reduce lithography variations, and reducing the iso-dense loading in the etch or deposition processes.

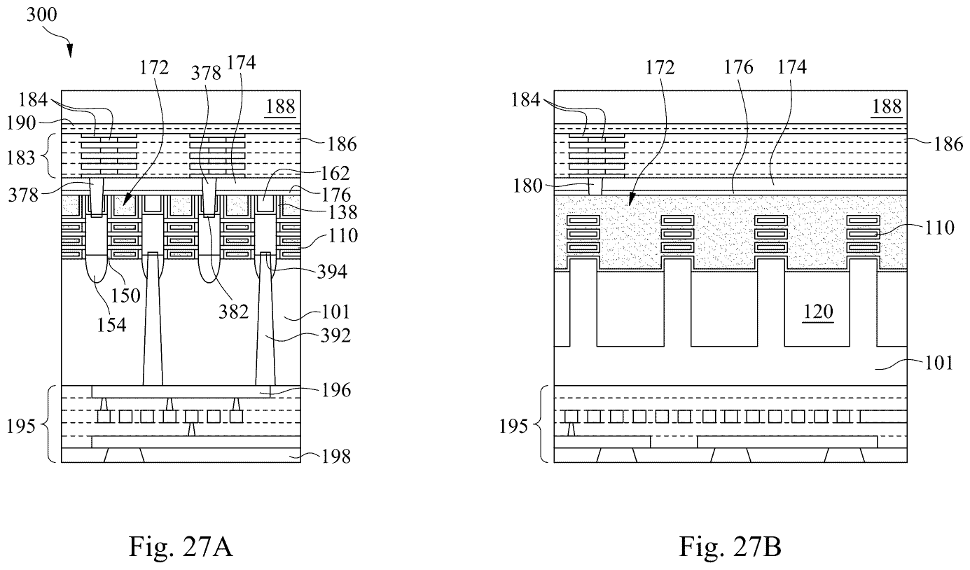

FIGS. 27A and 27B illustrate cross-sectional views of the semiconductor device 300, in accordance with some embodiments. The semiconductor device 300 is similar to the semiconductor device 100 or 200 and can include any suitable features of the semiconductor device 100 or 200, wherein the like reference numeral refers to a like element. The semiconductor device 300 may be formed by processes illustrated in FIGS. 1A-23B and 25A-25B, in accordance with some embodiments. In FIGS. 27A and 27B, the contacts 392/378 may extend into source/drain regions 158, in accordance with some embodiment. In some embodiments, the backside contacts 392 (including the silicide regions 394) vertically overlap the bottommost first nanostructure 110 (most adjacent to the substrate 101). In some embodiments, the frontside contacts 3378 also extend to vertically overlap the topmost first nanostructure 110 (most adjacent to the first ILD layer 162) to reduce the distance variation of the current paths, for example. The semiconductor device 400 provides more process tolerance to the etch processes for forming contacts 378 and contacts 392, in accordance with some embodiments.

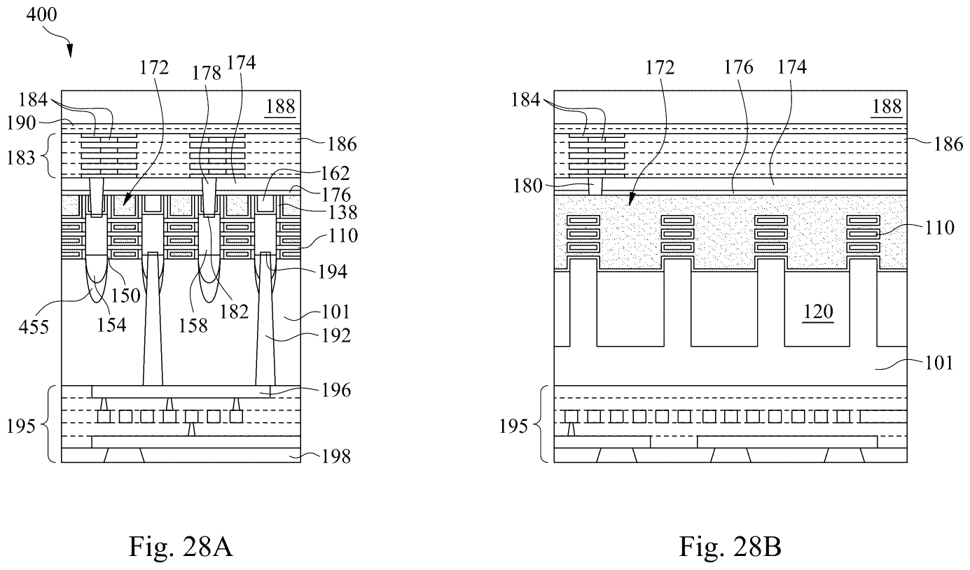

FIGS. 28A and 28B illustrate cross-sectional views of the semiconductor device 400, in accordance with some embodiments. The semiconductor device 400 is similar to the semiconductor device 100, 200, or 300 and can include any suitable features of the semiconductor device 100, 200, or 300, wherein the like reference numeral refers to a like element. The semiconductor device 400 may be formed by processes illustrated in FIGS. 1A-23B and 25A-25B, in accordance with some embodiments. In FIGS. 28A and 28B, the semiconductor device 400 includes a semiconductor filling 455 disposed between the dielectric filling 154 and the substrate 101. The semiconductor filling 455 may be a similar material to those of the substrate 101. For example, the semiconductor filling 455 may be single crystalline silicon. The semiconductor filling 455 may be formed by any suitable methods, such as an epitaxial deposition, and may be in-situ doped. In some embodiments, the semiconductor filling 455 may have dopants of a same type of the adjacent wells, such as p-type dopant for p-wells in an NMOS or n-type dopant for n-wells in a PMOS. The semiconductor filling 455 may be formed in the first openings 140 before forming the dielectric filling 154. In some embodiments, the semiconductor filling 455 may act as a buffer between the substrate 101 and the dielectric filling 145, such as reducing stress or minimizing the impact on the wells in the substrate (if doped).

Embodiments of the present disclosure provide a transistor structure including a plurality of nanostructure channels disposed between source/drain regions, and the plurality of the nanostructure channels have a same length. In some embodiments, the transistor structure also includes a frontside contact electrically coupled to a frontside of one of the source/drain regions and a backside contact electrically coupled to a backside of the other source/drain region. As such, regardless of which nanostructure channel the current transmits through, the lateral and vertical transmission distances of the current between the contacts would be fixed and substantially the same. The transistor structure of the present disclosure can, therefore, have a sharp on-off transition.

An embodiment is a semiconductor device that includes: a first channel region disposed over a semiconductor substrate; a gate structure disposed over the first channel region; a first source/drain region disposed at a first side of the first channel region; a second source/drain region disposed at a second side of the first channel region; an interlayer dielectric layer disposed over the first channel region, the first source/drain region, and the second source/drain region; a first contact disposed in the interlayer dielectric layer and electrically coupled to the first source/drain region; and a second contact disposed in the semiconductor substrate and electrically coupled to the second source/drain region. In an embodiment, the semiconductor device further includes a first dielectric filling between the first source/drain region and the semiconductor substrate. In an embodiment, the semiconductor device further includes a semiconductor filling disposed between the first dielectric filling and the semiconductor substrate. In an embodiment, the semiconductor further includes a second dielectric filling disposed between the first source/drain region and the semiconductor substrate, and the second contact extends through the semiconductor substrate and the second dielectric filling. In an embodiment, no conductive feature is disposed in the interlayer dielectric layer and electrically coupled to the second source/drain region. In an embodiment, the semiconductor device further includes a dummy contact disposed in the interlayer dielectric layer and connected to the second source/drain region; and a dielectric layer in contact with and completely covers a top surface of the dummy contact. In an embodiment, the semiconductor device further includes a second channel region disposed over the first channel region, wherein the first channel region and the second channel region have a same length, and the gate structure surrounds the first channel region and the second channel region.

Another embodiment is a semiconductor device that includes a semiconductor substrate having a frontside and a backside opposite to the frontside; a first channel region and a second channel region disposed over the frontside of the semiconductor substrate, wherein the first channel region and the second channel region have a same length and are disposed between a first epitaxial region and a second epitaxial region; a first contact disposed over the frontside of the semiconductor substrate and laterally aligned to the first epitaxial region; a first interconnect structure disposed over the frontside of the semiconductor substrate and electrically coupled to the first epitaxial region through the first contact; a second contact disposed in the semiconductor substrate and laterally aligned to the second epitaxial region; and a second interconnect structure disposed over the backside of the semiconductor substrate and electrically coupled to the second epitaxial region through the second contact. In an embodiment, the second interconnect structure includes a power rail. In an embodiment, the semiconductor device further includes a third contact disposed over the frontside of the semiconductor substrate and laterally aligned to the second epitaxial region, wherein the third contact is a dummy contact. In an embodiment, the first contact and the third contact have a same height. In an embodiment, the semiconductor device further includes a first dielectric filling separating the first epitaxial region from the semiconductor substrate. In an embodiment, the semiconductor device further includes a second dielectric filling separating the first epitaxial region from the semiconductor substrate, and the second contact extends through the second dielectric filling. In an embodiment, the first contact and the second contact each includes a silicide region. In an embodiment, the first interconnect structure and the second interconnect structure each includes bond pads for external connections.

A further embodiment is a method for forming a semiconductor device, the method includes: forming a first channel region disposed over a semiconductor substrate; forming a first source/drain region and a second source/drain region on a first side and a second side of the first channel region, respectively; forming an interlayer dielectric layer disposed over the first channel region, the first source/drain region, and the second source/drain region; forming a gate structure over the first channel region; forming a first contact in the interlayer dielectric layer, wherein the first contact is electrically coupled to the first source/drain region; and forming a second contact in the semiconductor substrate, wherein the second contact is electrically coupled to the second source/drain region. In an embodiment, the forming the first source/drain region includes forming an opening exposing the first side of the first channel region and depositing an epitaxial structure in the opening, wherein the method further includes depositing a dielectric filling in the opening before depositing the epitaxial structure. In an embodiment, the method further includes forming a second channel region and a third channel region below the first channel region when forming the first channel region, wherein the opening includes a first portion exposing the second channel region and the third channel region and a second portion below the first portion, wherein the first portion of the opening has a fixed width, and the second portion of the opening has gradually narrowed widths. In an embodiment, the method further includes forming a first interconnect structure over the first contact before forming the second contact. In an embodiment, the method further includes forming a second interconnect structure at a side of the semiconductor substrate away from the first interconnect structure, wherein the second interconnect structure includes a power rail.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first channel region disposed over a semiconductor substrate;
a gate structure disposed over the first channel region;
a first source/drain region disposed at a first side of the first channel region;
a second source/drain region disposed at a second side of the first channel region;
an interlayer dielectric layer disposed over the first channel region, the first source/drain region, and the second source/drain region;
a first contact disposed in the interlayer dielectric layer and electrically coupled to the first source/drain region; and
a second contact disposed in the semiconductor substrate and electrically coupled to the second source/drain region.

2. The semiconductor device of claim 1, further comprising a first dielectric filling between the first source/drain region and the semiconductor substrate.

3. The semiconductor device of claim 2, further comprising a semiconductor filling disposed between the first dielectric filling and the semiconductor substrate.

4. The semiconductor device of claim 1, further comprising a second dielectric filling disposed between the first source/drain region and the semiconductor substrate, and the second contact extends through the semiconductor substrate and the second dielectric filling.

5. The semiconductor device of claim 1, wherein no conductive feature is disposed in the interlayer dielectric layer and electrically coupled to the second source/drain region.

6. The semiconductor device of claim 1, further comprising:
a dummy contact disposed in the interlayer dielectric layer and connected to the second source/drain region; and
a dielectric layer in contact with and completely covers a top surface of the dummy contact.

7. The semiconductor device of claim 1, further comprising a second channel region disposed over the first channel region, wherein the first channel region and the second channel region have a same length, and the gate structure surrounds the first channel region and the second channel region.

8. A semiconductor device, comprising:
a semiconductor substrate having a frontside and a backside opposite to the frontside;
a first channel region and a second channel region disposed over the frontside of the semiconductor substrate, wherein the first channel region and the second channel region have a same length and are disposed between a first epitaxial region and a second epitaxial region;
a first contact disposed over the frontside of the semiconductor substrate and laterally aligned to the first epitaxial region;
a first interconnect structure disposed over the frontside of the semiconductor substrate and electrically coupled to the first epitaxial region through the first contact;
a second contact disposed in the semiconductor substrate and laterally aligned to the second epitaxial region; and
a second interconnect structure disposed over the backside of the semiconductor substrate and electrically coupled to the second epitaxial region through the second contact.

9. The semiconductor device of claim 8, wherein the second interconnect structure comprises a power rail.

10. The semiconductor device of claim 8, further comprising a third contact disposed over the frontside of the semiconductor substrate and laterally aligned to the second epitaxial region, wherein the third contact is a dummy contact.

11. The semiconductor device of claim 10, wherein the first contact and the third contact have a same height.

12. The semiconductor device of claim 8, further comprising a first dielectric filling separating the first epitaxial region from the semiconductor substrate.

13. The semiconductor device of claim 8, further comprising a second dielectric filling separating the first epitaxial region from the semiconductor substrate, and the second contact extends through the second dielectric filling.

14. The semiconductor device of claim 8, wherein the first contact and the second contact each comprises a silicide region.

15. The semiconductor device of claim 8, wherein the first interconnect structure and the second interconnect structure each comprises bond pads for external connections.

16. A method of forming a semiconductor device, the method comprising:
forming a first channel region disposed over a semiconductor substrate;
forming a first source/drain region and a second source/drain region on a first side and a second side of the first channel region, respectively;
forming an interlayer dielectric layer disposed over the first channel region, the first source/drain region, and the second source/drain region;
forming a gate structure over the first channel region;
forming a first contact in the interlayer dielectric layer, wherein the first contact is electrically coupled to the first source/drain region; and
forming a second contact in the semiconductor substrate, wherein the second contact is electrically coupled to the second source/drain region.

17. The method of claim 16, wherein the forming the first source/drain region comprises forming an opening exposing the first side of the first channel region and depositing an epitaxial structure in the opening, wherein the method further comprises depositing a dielectric filling in the opening before depositing the epitaxial structure.

18. The method of claim 17, further comprising forming a second channel region and a third channel region below the first channel region when forming the first channel region, wherein the opening comprises a first portion exposing the second channel region and the third channel region and a second portion below the first portion, wherein the first portion of the opening has a fixed width, and the second portion of the opening has gradually narrowed widths.

19. The method of claim 16, further comprising forming a first interconnect structure over the first contact before forming the second contact.

20. The method of claim 19, further comprising forming a second interconnect structure at a side of the semiconductor substrate away from the first interconnect structure, wherein the second interconnect structure comprises a power rail.
